(19) United States
(12) Patent Application Publication
(10) Pub. No.: US 2024/0229241 A9
(43) Pub. Date: Jul. 11, 2024

(54) METHOD FOR IMPROVING ADHESION OF YTTRIUM-BASED THIN FILM

(71) Applicant: SHINRYO CORPORATION, Kitakyushu-shi (JP)

(72) Inventors: Yuriko YANAI, Kitakyushu-shi (JP); Yoshitaka OZAKI, Kitakyushu-shi (JP); Tomohiro MATSUMURA, Kitakyushu-shi (JP)

(21) Appl. No.: 18/527,081

(22) Filed: Dec. 1, 2023

Related U.S. Application Data
(63) Continuation of application No. PCT/JP2022/022659, filed on Jun. 3, 2022.

(30) Foreign Application Priority Data
Jun. 7, 2021 (JP) 2021-095109

(51) Int. Cl. C23C 16/56

(52) U.S. Cl. CPC C23C 16/56

(57) ABSTRACT

A method for more easily improving adhesion of an yttrium-based thin film to an aluminum substrate in a coated aluminum member having the yttrium-based thin film formed on the aluminum substrate is provided. A method for improving adhesion of an yttrium-based thin film to an aluminum substrate in a coated aluminum member having the yttrium-based thin film formed on the aluminum substrate comprises a BHF treatment step of bringing a surface of the yttrium-based thin film into contact with a buffered hydrofluoric acid solution.

### CROSS-REFERENCE TO RELATED APPLICATIONS

This application is a continuation of PCT application No. PCT/JP2022/022659 filed on Jun. 3, 2022, which is based on and claims priority to Japanese Patent Applications No. 2021-095109 filed on Jun. 7, 2021, the disclosures of which are incorporated herein by reference.

### TECHNICAL FIELD

The present invention relates to a method for improving adhesion of an yttrium-based thin film to an aluminum substrate.

### BACKGROUND ART

In manufacturing of semiconductors, plasma is used in, for example, sputtering, CVD (chemical vapor deposition), and etching process. For the purpose of improving the plasma resistance of semiconductor manufacturing equipment or a member of the equipment, the inner surface of the equipment or the surface of the member are coated with an yttrium-based film. For example, a member of semiconductor manufacturing equipment including an aluminum substrate having a surface coated with an yttrium-based film is known. However, the yttrium-based film has a disadvantage of easily peeling from the inner surface of the equipment or the surface of the member due to a slight impact during handling. Accordingly, suppressing the peeling of the yttrium-based film has been required.

In order to prevent the film from peeling, a method of forming a first intermediate layer made of yttrium oxide in advance before forming a thermal-sprayed film of yttrium fluoride on the surface of a component is disclosed in Patent Literature 1.

### CITATION LIST

### Patent Literature

Patent Literature 1: Japanese Patent No. 6378389

### SUMMARY OF INVENTION

### Technical Problem

However, the method in Patent Literature 1 is complicated in operation, having difficulty in improving adhesion of members in use, so that a method for more easily improving the adhesion of an yttrium-based film to an aluminum substrate has been required. Under such circumstances, an object of the present invention is to provide a method for more easily improving adhesion of an yttrium-based thin film to an aluminum substrate in a coated aluminum member having the yttrium-based thin film formed on the aluminum substrate.

### Solution to Problem

As a result of extensive research for solving the problem, the present inventors have found that the following inventions meet the objective, so that the present invention has been completed.

That is, the present invention relates to the following inventions.

<1> A method for improving adhesion of an yttrium-based thin film to an aluminum substrate in a coated aluminum member having the yttrium-based thin film formed on the aluminum substrate, comprising a BHF treatment step of bringing a surface of the yttrium-based thin film into contact with a buffered hydrofluoric acid solution.

<2> The method for improving adhesion of an yttrium-based thin film according to item <1>, wherein in the BHF treatment step, a surface of the yttrium-based thin film is brought into contact with a buffered hydrofluoric acid solution by spraying the buffered hydrofluoric acid solution onto the surface of the yttrium-based thin film, and/or bringing the surface of the yttrium-based thin film into contact with a fibrous product impregnated with the buffered hydrofluoric acid solution.

<3> The method for improving adhesion of an yttrium-based thin film according to item <1> or <2>, further comprising a cleaning step of cleaning the yttrium-based thin film brought into contact with the buffered hydrofluoric acid solution with water.

<4> The method for improving adhesion of an yttrium-based thin film according to any one of items <1> to <3>, wherein the yttrium-based thin film is a thermal-sprayed film.

<5> The method for improving adhesion of an yttrium-based thin film according to any one of items <1> to <3>, wherein the yttrium-based thin film is a vapor-deposited film.

### Advantageous Effects of Invention

According to the present disclosure, the adhesion of an yttrium-based thin film to an aluminum substrate is more easily improved.

### BRIEF DESCRIPTION OF DRAWINGS

FIG. 1 is a photograph of appearances of a test piece (Al-1) before performing Example 1 (before treatment) and a test piece (Al-1) after performing Example 1 (after treatment).

FIG. 2 is a photograph of appearances of a test piece (Al-1) before performing Comparative Example 2 (before treatment) and a test piece (Al-1) after performing Comparative Example 2 (after treatment).

FIG. 3 is a photograph of appearances of a test piece (SUS) before performing Reference Example 1 (before treatment) and a test piece (SUS) after performing Reference Example 1 (after treatment).

FIG. 4 is a diagram for illustrating the method for evaluating adhesion.

FIG. 5 is a diagram for illustrating the method for calculating a fracture area ratio.

FIG. 6 is a photograph of appearances of a test piece (Al-2) before performing Example 2 (before treatment) and a test piece (Al-2) after performing Example 2 (after treatment).

### DESCRIPTION OF EMBODIMENT

Embodiments of the present invention will be described in detail below. The following description of constituent features is an example (typical example) of embodiments of the present invention. The present invention is not limited to the following content as long as the gist thereof is not changed. In the following, an expression “to” is used to indicate a range including the numerical values or physical properties pre- and post-positioned on the “to”, respectively.

<Method for Improving Adhesion of Yttrium-Based Thin Film>

The present invention relates to a method for improving adhesion of an yttrium-based thin film to an aluminum substrate in a coated aluminum member having the yttrium-based thin film formed on the aluminum substrate, comprising a BHF treatment step of bringing a surface of the yttrium-based thin film into contact with a buffered hydrofluoric acid solution (hereinafter sometimes referred to as “method of the present invention”).

Conventionally, use of buffered hydrofluoric acid has been considered to be unsuitable for an aluminum substrate, because the acid dissolves aluminum. However, the present inventors have found that by a BHF treatment of bringing a surface of the yttrium-based thin film formed on an aluminum substrate into contact with a buffered hydrofluoric acid solution, adhesion of the yttrium-based thin film to the aluminum substrate can be easily improved (enhanced). In particular, it has been found that, by conducting a BHF treatment by spraying or by using a fibrous product impregnated with a buffered hydrofluoric acid solution, adhesion of the yttrium-based thin film to the aluminum substrate can be easily improved.

[Coated Aluminum Member]

The coated aluminum member to which the method of the present invention is applied is a member having an yttrium-based thin film formed on an aluminum substrate. In particular, it is preferable to apply the method of the present invention to a coated aluminum member used inside semiconductor manufacturing equipment. The method of the present invention may be applied to an unused member, or to a member of semiconductor manufacturing equipment in use, so as to improve adhesion of the yttrium-based thin film.

The aluminum substrate that constitutes the coated aluminum member is a substrate containing aluminum. Examples of materials constituting the aluminum substrate include elemental aluminum, aluminum alloys, aluminum oxides, aluminum ceramics such as aluminum nitrides, mixtures thereof, and mixtures with other inorganic oxides.

The yttrium-based thin film formed on the aluminum substrate is preferably yttrium oxide (Y₂O₃), yttrium fluoride (YF₃), or yttrium oxyfluoride (YOF), more preferably yttrium oxide (Y₂O₃) or yttrium oxyfluoride (YOF), and still more preferably yttrium oxide (Y₂O₃). Although the film thickness of the yttrium-based thin film is not particularly limited, it is preferably 0.5 to 500 μm, more preferably 0.8 to 350 μm, still more preferably 1 to 200 μm. With a too thin film thickness of the yttrium-based thin film, peeling of the yttrium-based thin film and discoloration of aluminum tend to occur. On the other hand, with a film thickness of the yttrium-based thin film of more than 500 μm, adhesion of the yttrium-based thin film is hardly improved.

The film thickness of the yttrium-based thin film may be 5 to 500 μm, 10 to 500 μm, 30 to 350 μm, 50 to 200 μm, or the like.

The yttrium-based thin film may be formed on a portion where plasma resistance is required corresponding to the application of the coated aluminum member (for example, an inner wall of semiconductor manufacturing equipment). Methods for forming the yttrium-based thin film include PVD such as vacuum deposition, sputtering and ion plating, CVD, and thermal spraying. Examples of thermal spraying include thermal spraying such as flame spraying, high velocity flame spraying (HVOF), plasma thermal spraying and detonation thermal spraying, cold spraying, and aerosol deposition. A vapor-deposited film formed by vapor deposition (for example, vacuum vapor deposition) or a thermal-sprayed film formed by thermal spraying is preferred.

For example, the vapor-deposited film may have a thickness of 0.1 to 10 μm, 0.5 to 5 μm, or 0.8 to 3 μm. The thermal-sprayed film may have a thickness of 5 to 500 μm, 10 to 500 μm, 30 to 350 μm, or 50 to 200 μm.

[BHF Treatment Step]

The BHF treatment step is a step of bringing the surface of the yttrium-based thin film formed on the aluminum substrate into contact with a buffered hydrofluoric acid solution. In the BHF treatment step, the surface of the yttrium-based thin film can be brought into contact with a buffered hydrofluoric acid solution by spraying the buffered hydrofluoric acid solution onto the surface of the yttrium-based thin film, bringing the surface of the yttrium-based thin film into contact with a fibrous product impregnated with the buffered hydrofluoric acid solution, or immersing only the surface of the yttrium-based thin film in the buffered hydrofluoric acid solution. In particular, it is preferable that the surface of the yttrium-based thin film be brought into contact with a buffered hydrofluoric acid solution by spraying the buffered hydrofluoric acid solution onto the surface of the yttrium-based thin film, and/or bringing the surface of the yttrium-based thin film into contact with a fibrous product impregnated with the buffered hydrofluoric acid solution. In the method of immersing in the buffered hydrofluoric acid solution, the aluminum substrate and yttrium-based thin film tend to be discolored, so that more strict control of the composition of the buffered hydrofluoric acid solution, treatment time, treatment temperature, etc. is required. By spraying a buffered hydrofluoric acid solution or bringing into contact with a fibrous product impregnated with a buffered hydrofluoric acid solution, adhesion of the yttrium-based thin film can be more easily improved without discoloration.

The buffered hydrofluoric acid solution may be sprayed using an atomizer such as a general sprayer. Specifically, the contact between the surface of the yttrium-based thin film and the fibrous product impregnated with the buffered hydrofluoric acid solution is achieved by brushing (wiping) the surface of the yttrium-based thin film with a fibrous product wetted with the buffered hydrofluoric acid solution so as to spread the buffered hydrofluoric acid, or by covering the yttrium-based thin film with a fibrous product wetted with the buffered hydrofluoric acid solution. The fibrous product may be any material that can be impregnated with a buffered hydrofluoric acid solution, and may be appropriately selected from non-woven fabrics, cloths, paper, sponges, rollers, etc. The material of the fibrous product may be appropriately selected from polyethylene, polyester, polyurethane, cellulose, natural fiber, etc.

(Buffered Hydrofluoric Acid Solution)

The buffered hydrofluoric acid solution is a solution containing hydrofluoric acid and/or ammonium hydrogen fluoride and ammonium fluoride.

The buffered hydrofluoric acid may be prepared, for example, by mixing an aqueous hydrofluoric acid solution and an aqueous ammonium fluoride solution. On this occasion, the concentration of hydrofluoric acid in the buffered hydrofluoric acid solution is preferably 0.01 to 50 mass %, more preferably 1.0 to 30 mass %, and still more preferably 3.0 to 10 mass %. With a concentration of less than 0.01 mass %, the effect of improving adhesion of the yttrium-based thin film is hardly obtained. With a concentration of more than 50 mass %, peeling of the yttrium-based thin film and discoloration of aluminum tend to occur. The concentration of ammonium fluoride is preferably 10 to 45 mass %, more preferably 20 to 42 mass %, and still more preferably 30 to 40 mass %.

Alternatively, the buffered hydrofluoric acid may be prepared by mixing an aqueous ammonium hydrogen fluoride solution and an aqueous ammonium fluoride solution. On this occasion, the concentration of ammonium hydrogen fluoride in the buffered hydrofluoric acid solution is preferably 0.03 to 45 mass %, more preferably 1.0 to 30 mass %, and still more preferably 5.0 to 20 mass %. With a concentration of less than 0.03 mass %, the effect of improving adhesion of the yttrium-based thin film is hardly obtained. With a concentration of more than 45 mass %, peeling of the yttrium-based thin film and discoloration of aluminum tend to occur. The concentration of ammonium fluoride is preferably 0.1 to 45 mass %, more preferably 15 to 40 mass %, and still more preferably 20 to 35 mass %.

With concentrations of hydrofluoric acid, ammonium hydrogen fluoride, and ammonium fluoride within the ranges, adhesion of the yttrium-based thin film can be improved without peeling of the yttrium-based thin film or discoloration of aluminum.

(Treatment Time Period)

The time period for the treatment with the buffered hydrofluoric acid solution is not particularly limited. With a too long treatment time period, problems such as peeling of the yttrium-based thin film and discoloration of the aluminum substrate tend to occur, while with a too short treatment time period, a problem of not improving adhesion of the yttrium-based thin film occurs. Accordingly, the lower limit of the treatment time period is preferably 0.5 minutes or more, more preferably 10 minutes or more, and still more preferably 30 minutes or more. Also, the upper limit of the treatment time period is preferably 180 minutes or less, more preferably 120 minutes or less, and still more preferably 60 minutes or less. For example, the treatment time period may be 0.5 to 180 minutes, 10 to 120 minutes, or 30 to 60 minutes. As shown in Examples, the BHF treatment step may be performed multiple times, with cleaning after a BHF treatment and performing another BHF treatment again. In that case, it is preferable that the treatment time period for a BHF treatment be within the range.

(Treatment Temperature)

Although the treatment temperature is not particularly limited, with a too high treatment temperature, a problem of discoloration of the aluminum substrate tends to occur, while with a too low treatment temperature, a problem of not improving the adhesion of the yttrium-based thin film tends to occur. Accordingly, the lower limit of the treatment temperature is preferably 5° C. or more, more preferably 10° C. or more, and still more preferably 15° C. or more. Also, the upper limit of the treatment temperature is preferably 80° C. or less, more preferably 40° C. or less, and still more preferably 25° C. or less. For example, the treatment temperature may be 5 to 80° C., 10 to 40° C., or 15 to 25° C.

[Cleaning Step]

The method of the present invention usually has a cleaning step of cleaning the yttrium-based thin film brought into contact with the buffered hydrofluoric acid solution with water after the BHF treatment step. As the water used in the cleaning step, tap water, ultrapure water, ion-exchanged water, etc. may be used, and use of ultrapure water or ion-exchanged water is preferred.

The method of cleaning with water is not particularly limited, and examples thereof include soak cleaning, ultrasonic cleaning, high-pressure water cleaning, and running water cleaning. Among them, soak cleaning and running water cleaning are preferred to prevent peeling of the yttrium-based thin film.

(Cleaning Time Period)

Although the cleaning time period is not particularly limited, a too short cleaning time period tends to cause a problem of residual buffered hydrofluoric acid. Accordingly, the lower limit of the cleaning time period is preferably 0.5 minutes or more, more preferably 10 minutes or more, and still more preferably 60 minutes or more. The upper limit of the cleaning time period is not particularly limited, and may be, for example, 150 minutes or less or 90 minutes or less. For example, the cleaning time period may be 0.5 to 150 minutes, 10 to 150 minutes, or 60 to 90 minutes.

(Cleaning Temperature)

Although the cleaning temperature is not particularly limited, a problem of discoloration of the aluminum substrate tends to occur with too high cleaning temperature, and a problem of residual buffered hydrofluoric acid tends to occur with too low cleaning temperature. Accordingly, the lower limit of the cleaning temperature is preferably 5° C. or more, more preferably 10° C. or more, and still more preferably 15° C. or more. Also, the upper limit of the cleaning temperature is preferably 80° C. or less, more preferably 60° C. or less, and still more preferably 30° C. or less. For example, the cleaning temperature may be 5 to 80° C., 10 to 60° C., or 15 to 30° C.

After the cleaning step, drying such as vacuum drying, hot-air drying, and blast drying is performed to obtain a coated aluminum member with improved adhesion of the yttrium-based thin film to the aluminum substrate.

According to the method of the present invention, for example, as shown in Examples, the tensile adhesion strength of the yttrium-based thin film can be improved to 9.5 N/mm² or more, 10 N/mm² or more, 10.5 N/mm² or more, 15 N/mm² or more, or 20 N/mm² or more. As described above, the coated aluminum member can be used as a member of semiconductor manufacturing equipment or the like.

### EXAMPLES

The present invention will be described in more detail with reference to Examples in the following, though the present invention is not limited to the following Examples as long as the gist thereof is not changed.

<Test Piece Used>
Test piece (Al-1): An Al substrate (A5083, 40 mm square, 2 mm thick) having one surface thermal-sprayed with an yttrium oxide (Y₂O₃) thin film (120 μm). For use in evaluation of adhesion, the surface on substrate side (the side having no yttrium oxide thin film thermal-sprayed) was roughened (Scotch-Brite #7440).
Test piece (SUS): An SUS substrate (SUS304L, 40 mm square, 2 mm thick) having one surface thermal-sprayed with yttrium oxide (Y₂O₃) thin film (120 μm). For use in evaluation of adhesion, the surface of substrate side (the side having no yttrium oxide thin film thermal-sprayed) was roughened (Scotch-Brite #7440).
Test piece (Al-2): An Al substrate (A5083, 50 mm square, 2 mm thick) having one surface with a yttrium oxide (Y₂O₃) thin film (1 μm) vacuum-deposited. For use in evaluation of adhesion, the surface on substrate side (the side having no yttrium oxide thin film vacuum-deposited) was roughened (sandblasted with WA #60).

<Treatment Liquid Used, Etc.>
Buffered hydrofluoric acid solution (BHF solution): 110-BHF (manufactured by Morita Chemical Industries Co., Ltd., 13.5 mass % of ammonium hydrogen fluoride, 27.5 mass % by of ammonium fluoride, water as balance)
Tartaric acid solution: manufactured by FUJIFILM Wako Pure Chemical Corporation, 99.5 mass % tartaric acid solution
Water: ultrapure water (electric resistivity: 18 MΩ·cm)

### Example 1

A test piece (Al-1) was subjected to the following operations in order from s1 to s6 at normal temperature (15 to 20° C.)
s1: The surface of the test piece (Al-1) on the yttrium oxide thin film side was cleaned with water.
s2: Subsequently, the surface of the yttrium oxide thin film was wetted with a buffered hydrofluoric acid solution and left for 10 minutes. (BHF treatment step)
s3: The surface on the yttrium oxide thin film side was cleaned with water. (Cleaning step)
s4: The operation of s2 was performed again, and then the operations of s3 and s2 were further performed.
s5: The test piece (Al-1) after subjected to a third operation of s2 was immersed in warm water at 60° C. for 1 hour.
s6: The test piece (Al-1) was taken out from the warm water, subjected to high-pressure water cleaning and ultrasonic cleaning, and vacuum dried at 65° C. for 1 hour.

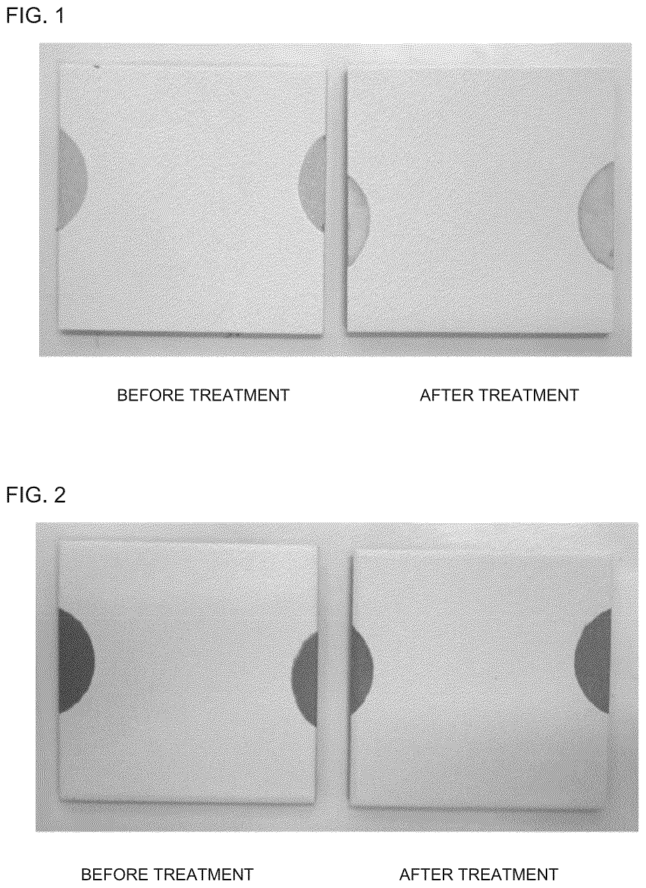

In FIG. 1, a photograph of appearances of the test piece (Al-1) before performing Example 1 (before treatment) and the test piece (Al-1) after performing Example 1 (after treatment) is shown. No significant difference in appearance was identified on the surface of the yttrium thin film between before and after treatment.

### Comparative Example 1

After a test piece (Al-1) was subjected to high-pressure water cleaning and ultrasonic cleaning, vacuum drying was performed at 65° C. for 1 hour.

### Comparative Example 2

The procedure was the same as in Example 1, except that a tartaric acid solution was used instead of the buffered hydrofluoric acid solution used in Example 1.

In FIG. 2, a photograph of appearances of the test piece (Al-1) before performing Comparative Example 2 (before treatment) and the test piece (Al-1) after performing Comparative Example 2 (after treatment) is shown. Although no significant difference in appearance was identified on the surface of the yttrium thin film between before and after treatment, discoloration was identified on the aluminum substrate portion.

### Reference Example 1

The procedure was the same as in Example 1 except that a test piece (SUS) was used instead of the test piece (Al-1).

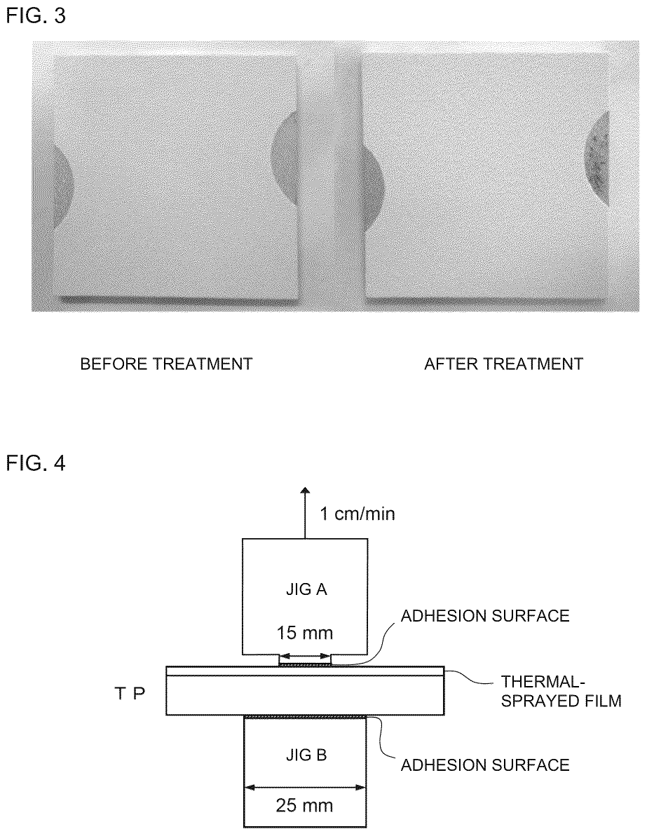

In FIG. 3, a photograph of appearances of the test piece (SUS) before performing Reference Example 1 (before treatment) and the test piece (SUS) after performing Reference Example 1 (after treatment) is shown. The surface of the treated test piece on the yttrium thin film side was slightly tinged with yellow.

### Reference Example 2

The procedure was the same as in Comparative Example 1 except that a test piece (SUS) was used instead of the test piece (Al-1).

<Evaluation of Adhesion>

Five test pieces were prepared for evaluation of adhesion, and an arithmetic average (Ave.) and sample standard deviation (Stdev.) of the respective values were obtained. As shown in FIG. 4, the adhesion was evaluated using a test piece (TP) after treatment, a jig A (material: SUS) having a protrusion with a diameter of 15 mm and a length of 30 mm, and a jig B (material: SUS) with a diameter of 25 mm and a length of 25 mm. The upper surface of the protrusion of jig A was adhered to the yttrium thin film (thermal-sprayed film) side of the resulting test piece (TP) with an epoxy adhesive, and jig B was adhered to the substrate side with an epoxy resin adhesive, so that a specimen was prepared. The specimen was attached to a tensile tester and pulled at a tensile speed of 1 cm/min to determine the tensile fracture load (N). Further, the state of the fracture surface was identified, and the ratio of complete peeling at the interface between the substrate and the thermal-sprayed film and complete peeling within the thermal-sprayed film in the adhesion area was calculated to determine the fracture area ratio (%). Tensile adhesion strength (N/mm²)=Tensile fracture load (N)/(Adhesion area between thermal-sprayed film and jig A (mm²)×Fracture area ratio (%)) was then determined. Measurement was performed according to JIS H8402 (2004) except for the specimen, tensile tester, and tensile speed.

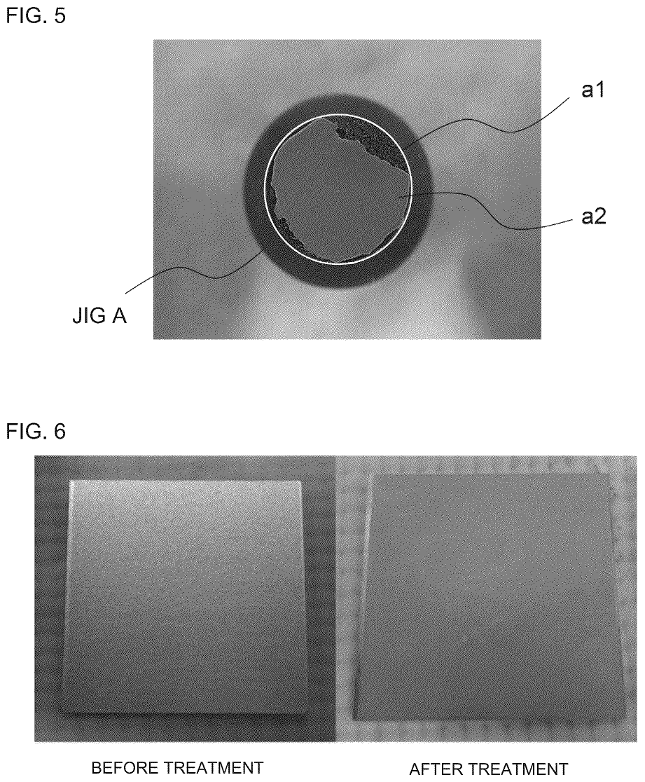

The fracture area ratio (%) was calculated from the fracture surface on the jig A side. Specifically, as shown in FIG. 5, the proportion of the fracture surface area (area of a2 in FIG. 5) in the adhesion area between the thermal-sprayed film and jig A (area of circle a1 in FIG. 5) was defined as fracture surface area ratio (%).

In Table 1, evaluation results of adhesion of the test pieces of Example 1 are shown, in Table 2, evaluation results of adhesion of the test pieces of Comparative Example 1 are shown, and in Table 3, evaluation results of adhesion of the test pieces of Comparative Example 2 are shown. In Table 4, evaluation results of adhesion of the test pieces of Reference Example 1 are shown, and in Table 5, evaluation results of adhesion of the test pieces of Reference Example 2 are shown. As shown in Tables 1 to 5, in the case where the substrate is SUS or in the case where tartaric acid is used as the treatment liquid, almost no effect of improving adhesion is observed. In contrast, it has been found that in the case where buffered hydrofluoric acid is used as the treatment liquid to treat the yttrium thin film formed on the aluminum substrate, the adhesion can be improved.

TABLE 1

| | Example 1 (BHF treatment) | | | | | | |
|---|---|---|---|---|---|---|---|
| | | | | | | | Sample |
| | | | | | | Arithmetic | standard |
| | First | Second | Third | Fourth | Fifth | average | deviation |
| | time | time | time | time | time | (Ave.) | (Stdev.) |
| Tensile | 1154 | 1967 | 1526 | 2009 | 1794 | 1690.0 | 354.8 |
| fracture | | | | | | | |
| load [N] | | | | | | | |
| Fracture | 85.5 | 93.3 | 95.7 | 97 | 95.8 | 93.5 | 4.6 |
| area ratio | | | | | | | |
| [%] | | | | | | | |
| Tensile | 7.638 | 11.93 | 9.023 | 11.72 | 10.6 | 10.2 | 1.8 |
| adhesion | | | | | | | |
| strength | | | | | | | |
| [N/mm²] | | | | | | | |

TABLE 2

| | Comparative Example 1 (Water cleaning only) | | | | | | |
|---|---|---|---|---|---|---|---|
| | | | | | | | Sample |
| | | | | | | Arithmetic | standard |
| | First | Second | Third | Fourth | Fifth | average | deviation |
| | time | time | time | time | time | (Ave.) | (Stdev.) |
| Tensile | 890 | 752 | 1086 | 1274 | 1337 | 1067.8 | 248.3 |
| fracture | | | | | | | |
| load [N] | | | | | | | |
| Fracture | 83.4 | 70.6 | 88.3 | 79.3 | 99.2 | 84.2 | 10.6 |
| area ratio | | | | | | | |
| [%] | | | | | | | |
| Tensile | 6.039 | 6.028 | 6.96 | 9.091 | 7.627 | 7.1 | 1.3 |
| adhesion | | | | | | | |
| strength | | | | | | | |
| [N/mm²] | | | | | | | |

TABLE 3

| | Comparative Example 2 (Tartaric acid treatment) | | | | | | |
|---|---|---|---|---|---|---|---|
| | | | | | | | Sample |
| | | | | | | Arithmetic | standard |
| | First | Second | Third | Fourth | Fifth | average | deviation |
| | time | time | time | time | time | (Ave.) | (Stdev.) |
| Tensile | 868 | 1134 | 995 | 863 | 601 | 892.2 | 197.0 |
| fracture | | | | | | | |
| load [N] | | | | | | | |
| Fracture | 97.8 | 99.7 | 99.9 | 84.5 | 76.5 | 91.7 | 10.6 |
| area ratio | | | | | | | |
| [%] | | | | | | | |
| Tensile | 5.022 | 6.436 | 5.636 | 5.779 | 4.446 | 5.5 | 0.8 |
| adhesion | | | | | | | |
| strength | | | | | | | |
| [N/mm²] | | | | | | | |

TABLE 4

| | Reference Example 1 (BHF treatment) | | | | | | |
|---|---|---|---|---|---|---|---|
| | | | | | | | Sample |
| | | | | | | Arithmetic | standard |
| | First | Second | Third | Fourth | Fifth | average | deviation |
| | time | time | time | time | time | (Ave.) | (Stdev.) |
| Tensile | 1833 | 1303 | 1690 | 1254 | 1078 | 1431.6 | 316.6 |
| fracture | | | | | | | |
| load [N] | | | | | | | |
| Fracture | 99.3 | 93.9 | 89.5 | 84.1 | 82.7 | 89.9 | 6.9 |
| area ratio | | | | | | | |
| [%] | | | | | | | |
| Tensile | 10.45 | 7.852 | 10.69 | 8.438 | 7.376 | 9.0 | 1.5 |
| adhesion | | | | | | | |
| strength | | | | | | | |
| [N/mm²] | | | | | | | |

TABLE 5

| | Reference Example 2 (Water cleaning only) | | | | | | |
|---|---|---|---|---|---|---|---|
| | | | | | | | Sample |
| | | | | | | Arithmetic | standard |
| | First | Second | Third | Fourth | Fifth | average | deviation |
| | time | time | time | time | time | (Ave.) | (Stdev.) |
| Tensile | 877 | 1352 | 1698 | 1394 | 1407 | 1345.6 | 295.8 |
| fracture | | | | | | | |
| load [N] | | | | | | | |
| Fracture | 81.7 | 93.7 | 81.6 | 97.9 | 97.7 | 90.5 | 8.3 |
| area ratio | | | | | | | |
| [%] | | | | | | | |
| Tensile | 6.074 | 8.165 | 11.78 | 8.058 | 8.149 | 8.4 | 2.1 |
| adhesion | | | | | | | |
| strength | | | | | | | |
| [N/mm²] | | | | | | | |

### Example 2

The test piece (Al-2) was subjected to the following operations in order from s1 to s5 at normal temperature (15 to 20° C.)
s1: The surface of the test piece (Al-2) on the yttrium oxide thin film side was cleaned with water.
s2: Subsequently, the surface of the yttrium oxide thin film was wetted with a buffered hydrofluoric acid solution and left standing for 10 minutes. (BHF treatment step)
s3: The surface on the yttrium oxide thin film side was cleaned with water. (Cleaning step)
s4: The test piece was immersed in warm water at 60° C. for 1 hour.
s5: The test piece (Al-2) was taken out from the warm water, subjected to high-pressure water cleaning and ultrasonic cleaning, and vacuum dried at 65° C. for 1 hour.

In FIG. 6, a photograph of appearances of the test piece (Al-2) before performing Example 2 (before treatment) and the test piece (Al-2) after performing Example 2 (after treatment) is shown. The surface of the treated test piece on the yttrium thin film side was slightly darkened.

### Comparative Example 3

After the test piece (Al-2) was subjected to high-pressure water cleaning and ultrasonic cleaning, vacuum drying was performed at 65° C. for 1 hour.

<Evaluation of Adhesion>

Evaluation was performed in the same manner as in Example 1, except that one test piece of each Example 2 and Comparative Example 3 was prepared for evaluation of adhesion.

In Table 6, evaluation results of adhesion of the test pieces of Example 2 and Comparative Example 3 are shown. As shown in Table 6, it has been found that the adhesion can be improved by using buffered hydrofluoric acid as the treatment liquid to treat the vacuum deposited yttrium thin film formed on the aluminum substrate.

Further, through observation of the state of the fracture surface in Example 2, it has been found that the fracture occurred within the adhesive, not at the interface between the substrate and the vapor-deposited film nor within the vapor-deposited film. Accordingly, the adhesive strength between the substrate and the yttrium oxide thin film in Example 2 is expected to be more than the calculated tensile adhesive strength.

In Comparative Example 3, as in Example 1 and Comparative Examples 1 and 2, the fracture occurred at the interface between the substrate and the yttrium oxide thin film or within the yttrium oxide thin film.

TABLE 6

| | | Comparative |
|---|---|---|
| | Example 2 (BHF | Example 3 (Water |
| | treatment) | cleaning only) |
| Tensile fracture | 2401 | 995 |
| load [N] | | |
| Fracture area ratio | 57.5(*) | 40.5 |
| [%] | | |
| Tensile adhesion | 23.6(*) | 13.9 |
| strength [N/mm²] | | |

(*)Fracture occurred within adhesive, not at interface between substrate and thin film.

### INDUSTRIAL APPLICABILITY

The present invention can be used in fields such as semiconductor manufacturing equipment, and is industrially useful.

1. A method for improving adhesion of an yttrium-based thin film to an aluminum substrate in a coated aluminum member having the yttrium-based thin film formed on the aluminum substrate, comprising:
a BHF treatment step of bringing a surface of the yttrium-based thin film into contact with a buffered hydrofluoric acid solution.

2. The method for improving adhesion of an yttrium-based thin film according to claim 1, wherein in the BHF treatment step, a surface of the yttrium-based thin film is brought into contact with a buffered hydrofluoric acid solution by spraying the buffered hydrofluoric acid solution onto the surface of the yttrium-based thin film, and/or bringing the surface of the yttrium-based thin film into contact with a fibrous product impregnated with the buffered hydrofluoric acid solution.

3. The method for improving adhesion of an yttrium-based thin film according to claim 1, further comprising a cleaning step of cleaning the yttrium-based thin film brought into contact with the buffered hydrofluoric acid solution with water.

4. The method for improving adhesion of an yttrium-based thin film according to claim 1, wherein the yttrium-based thin film is a thermal-sprayed film.

5. The method for improving adhesion of an yttrium-based thin film according to claim 1, wherein the yttrium-based thin film is a vapor-deposited film.
